(19) United States
(12) Patent Application Publication
(10) Pub. No.: US 2006/0120832 A1
(43) Pub. Date: Jun. 8, 2006

(54) Method and apparatus for handling a substrate

(76) Inventors: Rajeshwar Chhibber, San Jose, CA (US); David Willenborg, Pleasanton, CA (US); Chuck McKee, Colville, WA (US)

Correspondence Address: FERNANDEZ & ASSOCIATES LLP, 1047 EL CAMINO REAL, SUITE 201, MENLO PARK, CA, 94025, US

(21) Appl. No.: 10/984,568

(22) Filed: Nov. 8, 2004

(51) Int. Cl. H01L 21/677

(52) U.S. Cl. 414/217

(57) ABSTRACT

In one sense, the invention relates to a novel device for handling of substrates. The device has movable support arms configured to safely handle substrates, as well as gripping members for holding the substrate in place. The arms support the substrate, and the gripping members grab the substrate along its edges. The support arms then move away from the substrate. In this manner, the substrate is held in place by the grippers, along its edges. Because the support arms are moved away from the substrate surfaces, both sides of the substrate are thus exposed simultaneously, facilitating speed in processes such as inspection, and thus yielding greater process efficiency.

### BRIEF DESCRIPTION OF THE INVENTION

This invention relates generally to handling a substrate. More specifically, this invention relates to methods and apparatuses for handling substrates, and exposing these substrates during inspection.

### BACKGROUND OF THE INVENTION

Efficiency and the corresponding need for high throughput drives many aspects of the computer industry, including all types of substrate handling and inspection. Current substrates, whether they be semiconductor wafers, hard disk drives, or the like, must be handled quickly, reliably, and with minimal contamination or breakage during manufacturing process steps such as inspection. Substrate inspection is a critical process step and, as such, often requires the highest practicable throughput. However, certain process bottlenecks still exist. As one example, inspection of both sides of a substrate is commonly performed serially. That is, one side of the substrate is inspected, the substrate is flipped over, and then the other side is inspected. Such serial inspection reduces throughput, as compared to simultaneous inspection of both sides of the substrate.

However, while simultaneous inspection of both sides of the substrate is desirable from a throughput and/or process efficiency standpoint, certain technical hurdles must be overcome. For example, most current substrate handlers and supports are designed for single-sided inspection. As inspection of only one side of a substrate does not require that both sides of the substrate be simultaneously exposed, current substrate handlers typically obscure the side they are supporting. That is, they usually support, and thus obscure, the backside of the substrate while the front side is inspected. Backside inspection requires the substrate be removed from the inspection system, flipped over, then returned to the inspection system, and is thus not desirable due to the associated potential for contamination. One alternative is the grasping of substrates only at a few points along their edges, thus limiting contamination to those isolated points. However, current edge gripping handlers still obstruct one side of the substrate.

Accordingly, it is desirable to develop devices and methods for handling substrates, and supporting them during processes such as simultaneous inspection of both sides. More specifically, it is desirable to support substrate in such a way that both sides are sufficiently exposed for adequate inspection.

### SUMMARY OF THE INVENTION

The invention can be implemented in numerous ways, including as a method, system, and device. Various embodiments of the invention are discussed below.

In one embodiment of the invention, a substrate process chamber comprises a chamber configured to receive a substrate, and a plurality of substrate supports. The substrate supports are configured to engage the substrate so as to handle the substrate within the chamber. The support arms are configured to engage the substrate so as to maintain the substrate proximate to the substrate supports, and to disengage from the substrate once the substrate is engaged by the substrate supports.

In another embodiment of the invention, an apparatus for facilitating the support of a substrate within a chamber comprises a bracket, and movable arms pivotally affixed to the bracket. The arms are configured to move between a first position engaging a substrate so as to facilitate movement of the substrate, and a second position disengaged from the substrate so as to facilitate the performance of a process upon the substrate.

In another embodiment of the invention, a method of positioning a substrate comprises receiving a substrate upon a movable arm, engaging the substrate with the support members, and retracting the arm from the substrate so as to expose the substrate for the performance of a process thereon.

Other aspects and advantages of the invention will become apparent from the following detailed description taken in conjunction with the accompanying drawings which illustrate, by way of example, the principles of the invention.

### BRIEF DESCRIPTION OF THE DRAWINGS

For a better understanding of the invention, reference should be made to the following detailed description taken in conjunction with the accompanying drawings, in which:

FIG. 1 illustrates a wafer inspection chamber and its operation in accordance with embodiments of the current invention.

FIG. 2 illustrates further details of the wafer inspection chamber, including a wafer handler in accordance with the invention, for supporting a wafer while simultaneously exposing both sides of the wafer for inspection.

FIG. 3 illustrates further details of the handler, in accordance with embodiments of the current invention.

FIGS. 4A-4B illustrate details of the operation of the handler, in accordance with embodiments of the current invention.

FIGS. 5A-5B illustrate further details of the operation of the handler, in accordance with embodiments of the current invention.

FIG. 6 illustrates process steps in the use of the handler for wafer support and transport, in accordance with embodiments of the current invention.

FIGS. 7A-7D illustrate various embodiments of gripper ends of the handler, for contacting and supporting a wafer during simultaneous inspection of both sides of the wafer.

FIGS. 7E-7F illustrate still more embodiments of gripper ends of the handler.

Like reference numerals refer to corresponding parts throughout the drawings.

### DETAILED DESCRIPTION OF EMBODIMENTS OF THE INVENTION

In one sense, the invention relates to a novel device for handling of substrates. The handler has pivotable support arms configured to safely transport substrates, as well as edge gripping members for holding the substrate in place. The arms support the substrate from its backside edge, in proper position for the gripping members to grab the substrate along its edges. Once the gripping members engage the substrate, the support arms pivot away from the substrate. In this manner, the substrate is held in place by the grippers, along its edges. Because the support arms are moved away from the substrate surfaces, both sides of the substrate are exposed simultaneously, facilitating speed in processes such as inspection, and yielding greater process efficiency as well as lower particle contamination.

A discussion of embodiments of the invention follows. In these embodiments, methods and apparatuses are explained in the context of semiconductor wafer inspection. However, the invention is not limited to this context. Rather, the invention encompasses the handling and exposure of all types of substrates for any process, of which inspection is but one. As one example, while the arms and grippers can hold a substrate for inspection, they can also hold a substrate so as to carry out most any other process. They can also hold wafers for single-sided inspection and/or edge inspection, if necessary.

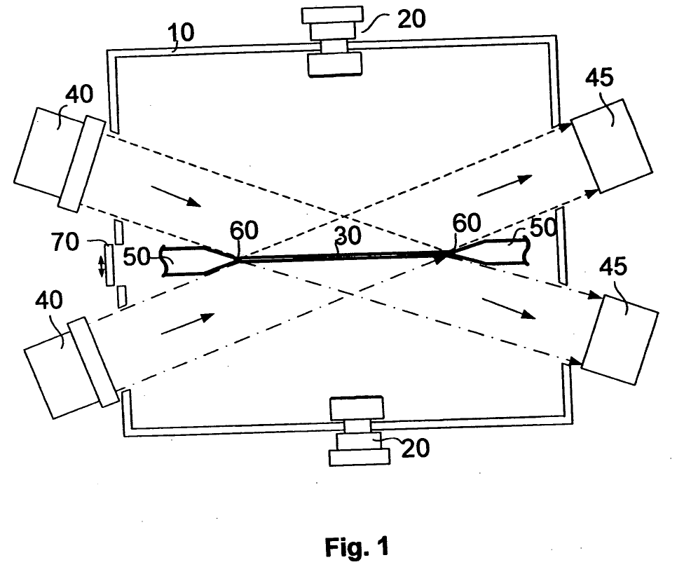

FIG. 1 illustrates a wafer inspection chamber and its operation. An inspection chamber 10 has inspection units 20, that can be any device capable of inspecting a semiconductor wafer 30 for defects. For example, the inspection units 20 can employ CCD/CMOS/CID linear or array sensors, photodetectors, or the like. Inspection can be performed according to any method, e.g., laser scanning, bright field or dark field (with or without source) scanning, etc. The embodiment shown employs dark field illumination, however any method can be used, and the invention is not limited by inspection or other process method. In this embodiment, light sources 40 emit light beams that provide sufficient simultaneous darkfield illumination of both wafer surfaces for defect detection by the inspection units 20, and that are absorbed by beam dumps 45. Scatter from wafer surface defects is detected by detectors 20. During inspection, the wafer 30 is held in place by grippers 50, which hold the wafer 30 in place solely along its edge 60. The door 70 opens (slides down, in this embodiment) to allow wafer 30 transfer in and out of the chamber 10, and closes (slides back upward) during inspection.

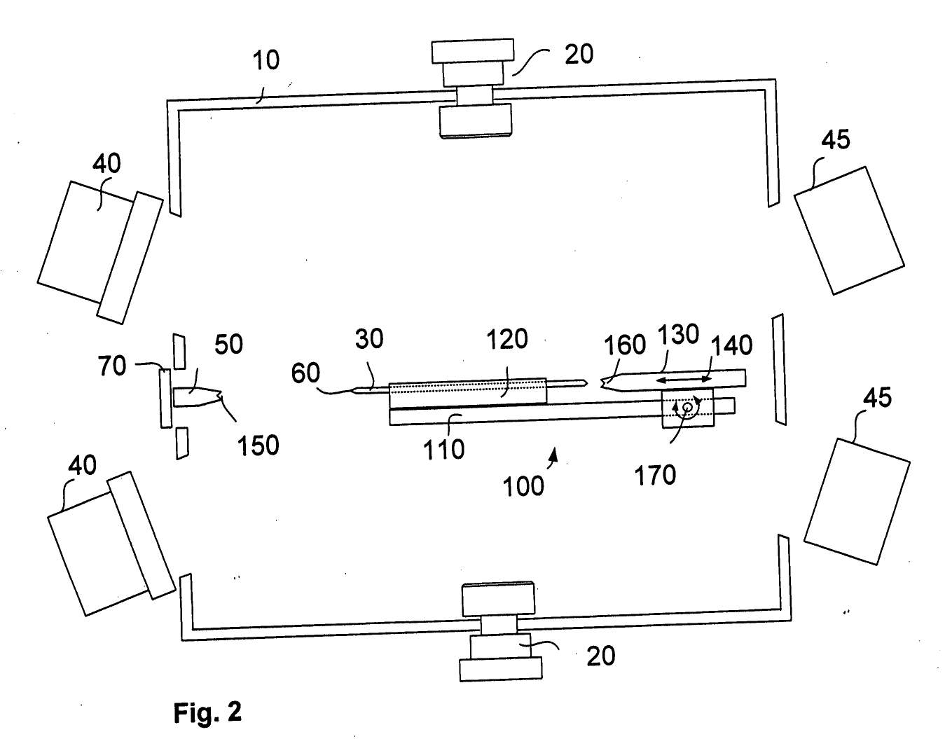

The wafer inspection chamber 10 employs a handler to support the wafer 30 within it for load/unload, and to grip the wafer 30 by its edge 60 for inspection. FIG. 2 illustrates further details of the chamber 10 and the handler. Here, the chamber 10 contains a gripping and transport handler 100 placed within. The handler 100 has arms 110 equipped with support pads 120 for holding the wafer 30 during wafer load/unload. In operation, the chamber door 70 moves downward to allow the wafer 30 to be loaded/unloaded into/out of the chamber 10, and onto/off of the support pads 120. Once a wafer 30 is placed on the arms 110, the door 70 is closed so as to align the attached gripper 50 with the wafer 30. The handler 100 also has a gripper 130 movably attached. This gripper 130 is constructed similar to its counterpart gripper 50, but is slidably attached to the handler 100 so as to be capable of movement in the direction of the arrows 140.

Once the handler 100 has the wafer 30 positioned on it and the gripper 50 is slid proximate (i.e., the door 70 is shut), the gripper 130 slides in the direction of the leftward arrow 140 to push the wafer 30 against the other gripper 50. In this configuration, the grippers 50, 130 have ends 150, 160 that hold the wafer 30. No longer needed to support the wafer 30 once the grippers 50, 130 are engaged, the arms 110 can then be moved away from the wafer 30, such as along a pivot axis 170, thus exposing the wafer 30 for inspection. Because the grippers 50, 130 hold the wafer 30 along its edge 60 and not along either its upper or lower surface, the grippers 50, 130 also leave the upper surface exposed for inspection, as shown in FIG. 1.

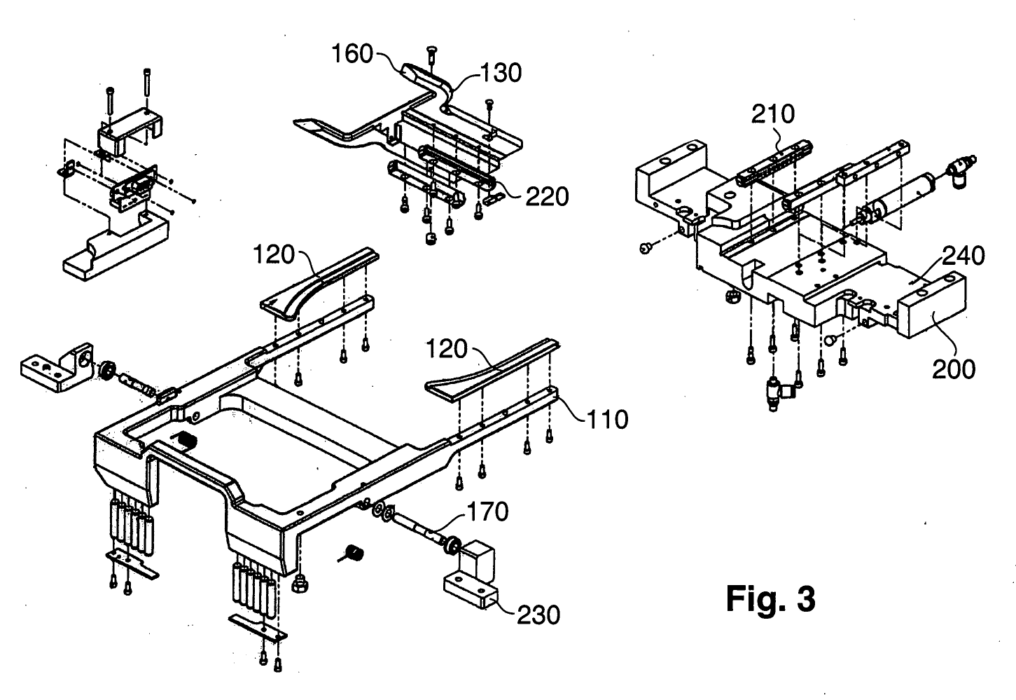

The basic concept and operation of the gripping and support handler 100 having been explained, FIG. 3 illustrates further details of one specific implementation. Here, the handler 100 comprises a support or bracket 200, arms 110 having support pads 120 as described above, and a pivot mechanism 170. One end of the pivot mechanism 170 is rotatably coupled to the arms 110 to allow the arms to pivot, while another end is attached to the bracket 200 by a bearing block 230 attached to the underside 240 of the bracket 200. The gripper 130 has inner linear bearing rails 220 that mate to outer linear bearing rails 210 affixed to the bracket 200, allowing the gripper 130 to slide along the bracket 200 toward or away from the wafer 30.

In some embodiments, it is convenient to provide a motor or some other mechanism for automatically or remotely sliding the gripper 130 along the rails 210. For instance, a precision servo motor can be employed to control the speed with which the gripper 130 is driven and to actuate the gripper 130 precisely against the side of the wafer 30 so as to avoid excessive forces that may damage the wafer 30. A high-viscosity grease that is compatible with the environment of the inspection chamber 10 could be employed to control the maximum velocity (and thus the initial force) of the gripper 130 as it contacts the wafer. For instance, a flourocarbon gel in the linear bearing 210, 220 may be employed to limit undesired gripper contact force on the wafer 30. In other embodiments, it is also convenient to provide actuation mechanisms that operate within the requirements of an inspection chamber 10. For example, the actuation mechanism can utilize a spring to push the gripper 130 toward the wafer 30, and a vacuum solenoid (which, like the spring, generates very few particulates) to retract the gripper 130. Such mechanisms are known, and are not shown here so as to avoid excessive detail that obscures the invention.

In connection with these mechanisms, it is also desirable to employ similar precision and/or low-particulate actuation mechanisms for vertical position control of the chamber door 70 in FIG. 2, especially in embodiments where the gripper 50 is attached to the door, as the height of the gripper 50 must be precisely controlled to avoid undesired stresses within the wafer 30 and inaccuracies in focus of the inspection units 20. It should be noted that the invention encompasses any and/or all such mechanisms discussed above.

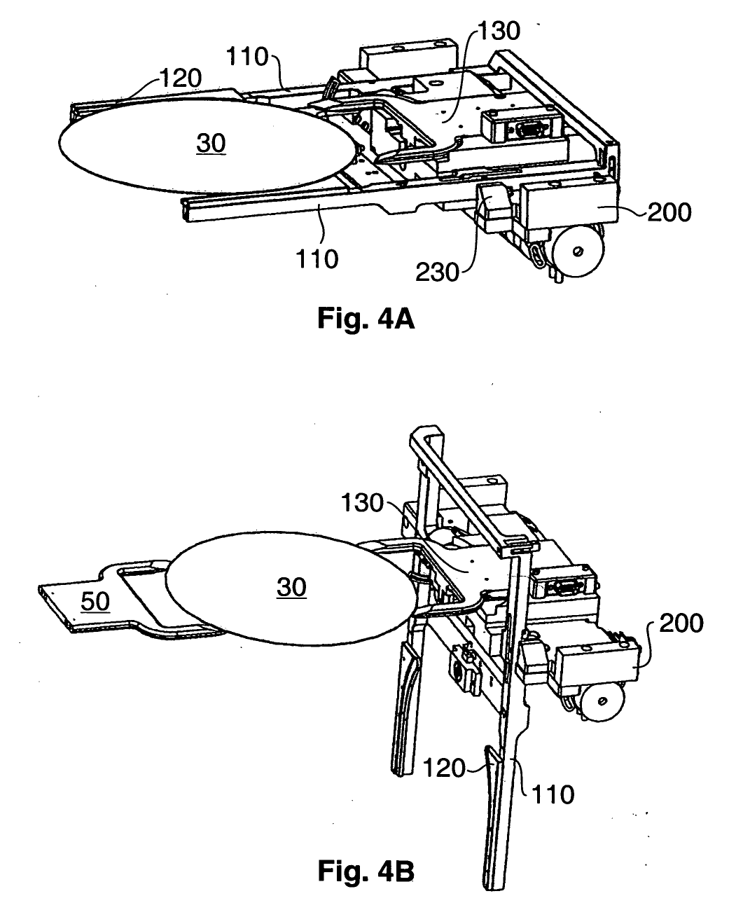

The operation of the pivotable arms 110 and the remainder of the handler 100 are further illustrated in FIGS. 4A-4B. As shown in FIG. 4A, the arms 110 rotate about the pivot 170 (obscured by the bearing block 230) into a first position which, in the embodiment of FIG. 2, is roughly horizontal, so as to hold the wafer 30 upon the support pads 120. When the gripper 50 is moved to engage the wafer 30 (which, as above, can be accomplished by an upward sliding of the door 70), the other gripper 130 can be slid toward the wafer along rails 220, so as to engage the wafer 30 securely between the two grippers 50, 130. The wafer 30 held securely by the grippers 50, 130, the arms 110 are no longer needed to support the wafer 30. The arms 110, with supports 120, can then be pivoted down and away from the wafer 30 into a second position, as shown in FIG. 4B. The arms 110 can be configured to pivot sufficiently far so as to be out of the field of view of the inspection units 20, however that need not necessarily be the case. However, if it is, inspection of both sides of the wafer can be performed simultaneously, as neither side is obscured by any part of the handler 100.

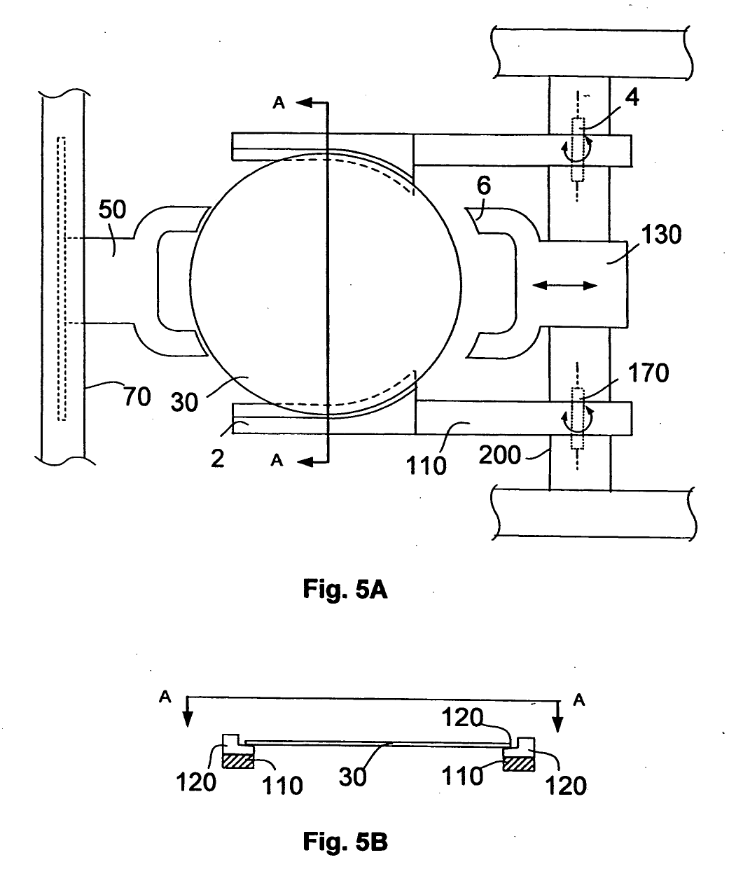

FIGS. 5A-5B illustrate diagrammatic top and cutaway side views, respectively, of the handler 100 while it supports a wafer 30. The views of FIGS. 5A-5B are helpful in highlighting the operation of the arms 110 in holding a wafer 30. As can be seen, when the arms 110 are in the first position, they can securely hold a wafer 30 upon their support pads 120. The support pads 120 can be made of any material capable of being placed in contact with the wafer 30 without damaging or contaminating it, such as PEEK or Vespel, for example. While the pads 120 can be shaped in any configuration suitable for supporting the wafer 30, it is in some instances preferable for the pads 120 to contact the wafer 30 upon as little of the surface of the wafer 30 as possible. Especially in contexts in which contamination of the supported surface of the wafer is to be avoided, the support pads 120 can be designed with contours 250 that follow the contour of the wafer 30 and allow for support of the wafer 30 while contacting it along as little surface area as possible.

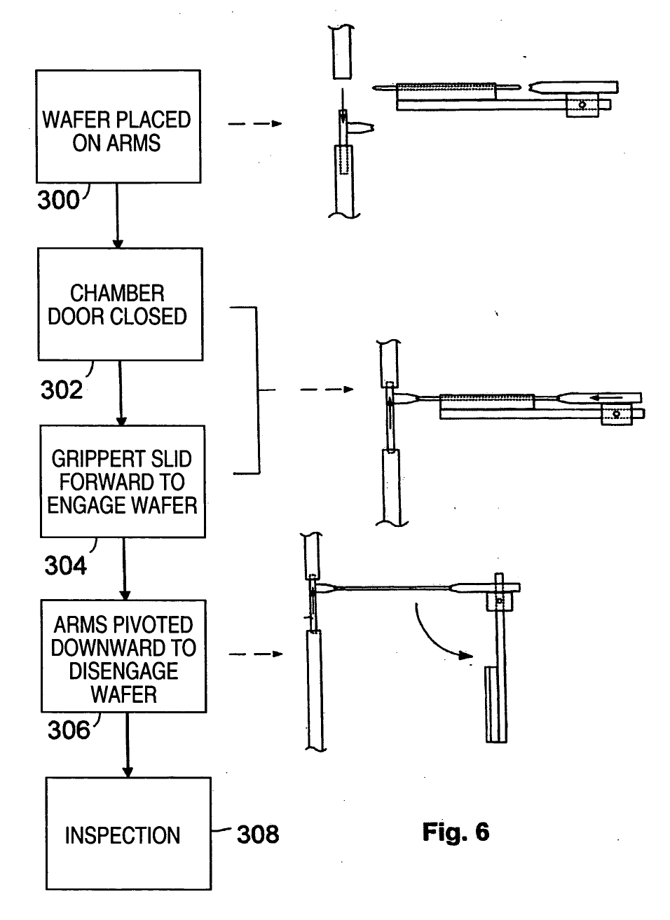

The configuration and operation of the handler 100 having been explained, process steps in its use within a chamber 10 are now explained. FIG. 6 illustrates process steps in the use of the handler 100 for wafer support and transport. The process typically begins with a wafer 30 being inserted into the chamber 10 for inspection. Typically, a robot (not shown) extends a wafer 30 through the door 70, where it is placed upon the support pads 120 (step 300). In alternate embodiments, the support arms 200 can extend out of the chamber 10, where a wafer 30 can be placed upon the arms 110.

Once the wafer is placed upon the pads 120, the chamber door 70 is closed (step 302) so as to align the gripper 50 with the wafer 30. The other gripper 130 on the bracket 200 is then slid toward the wafer 30, and pushes the wafer 30 against the gripper 50 so as to hold the wafer 30 between the two grippers 50, 130 (step 304). The wafer 30 is now held between the ends 150, 160 of the two grippers 50, 130, rendering the support pads 120 unnecessary for supporting the wafer 30. The arms 110 can then be pivoted away from the wafer (in this case, downward), so as to avoid obstructing the field of view of any of the inspection units 20 (step 306). Because the grippers 50, 130 grip only the side of the wafer 30, they do not obscure either the upper or lower surface. Also, the arms 110 are now no longer obscuring either surface. Simultaneous inspection of the upper and lower surfaces of the wafer 30 can thus be commenced (step 308).

Removal of the wafer 30 from the chamber 10 after inspection can be carried out essentially in reverse order of the steps of FIG. 6. That is, the arms 110 are pivoted upward into the first position so that the support pads 120 once again contact the wafer 30. The gripper 130 can then be slid away from the wafer 30, so that the grippers 50, 130 no longer grip or support the wafer 30, and the wafer 30 is supported solely by the arms 110 and support pads 120. The chamber door 70 can then be opened and the wafer 30 removed from the chamber 10.

While the handler 100 is constructed so that the arms 110 pivot downward in the orientation of FIGS. 3 and 4A-4B, the invention is not limited to this specific configuration. Rather, the invention simply contemplates arms 100 that are movable. Thus, the invention includes arm 100 configurations designed to translate away from the wafer 30 instead of pivoting. The invention also includes arm 100 configurations that pivot upward instead of downward, perhaps after moving laterally outward from the wafer 30 so as to first disengage the wafer 30. Also, the invention includes arm 110 configurations in which the arms 110 pivot laterally away from the wafer 30, and/or slide away from the wafer 30 instead of pivoting. One of skill will also realize that these alternate configurations of the arms 110 can be accomplished using known mechanisms. For instance, the arms 110 can be placed on tracks much like the tracks 210 that allow the gripper 130 to slide. Also, the pivot mechanism 170 can be placed so as to allow the arms 110 to pivot upward instead of downward. In such an embodiment, the arms 110 must first be moved laterally away from the wafer 30 so as to avoid colliding with the wafer 30 when the arms 110 are pivoted upward.

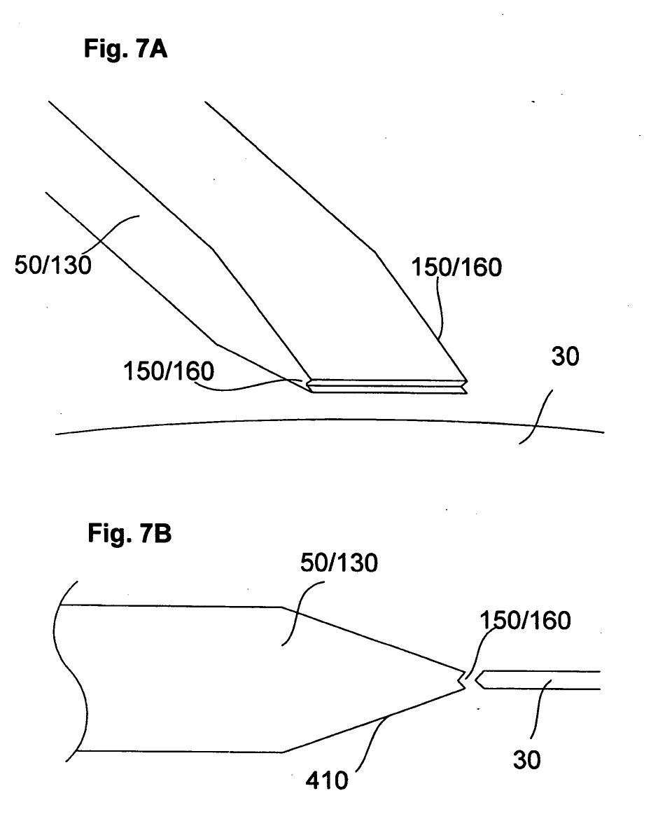

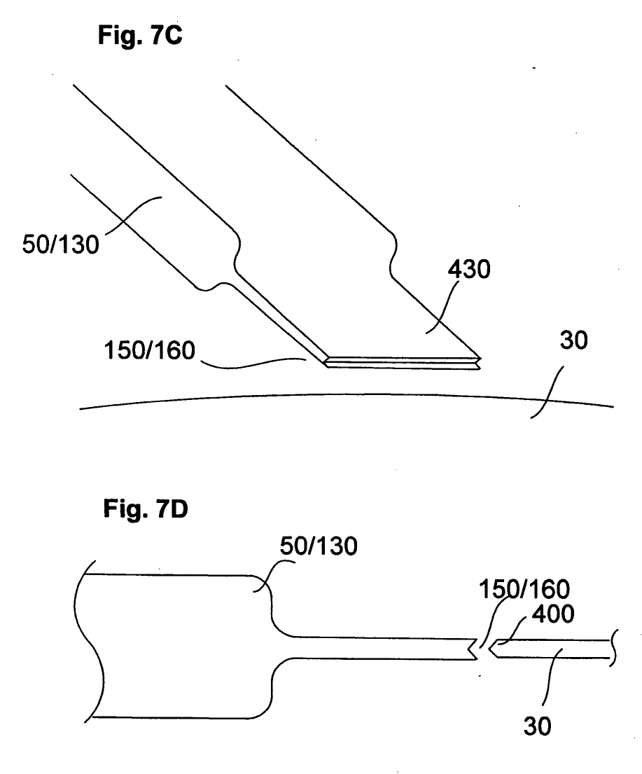

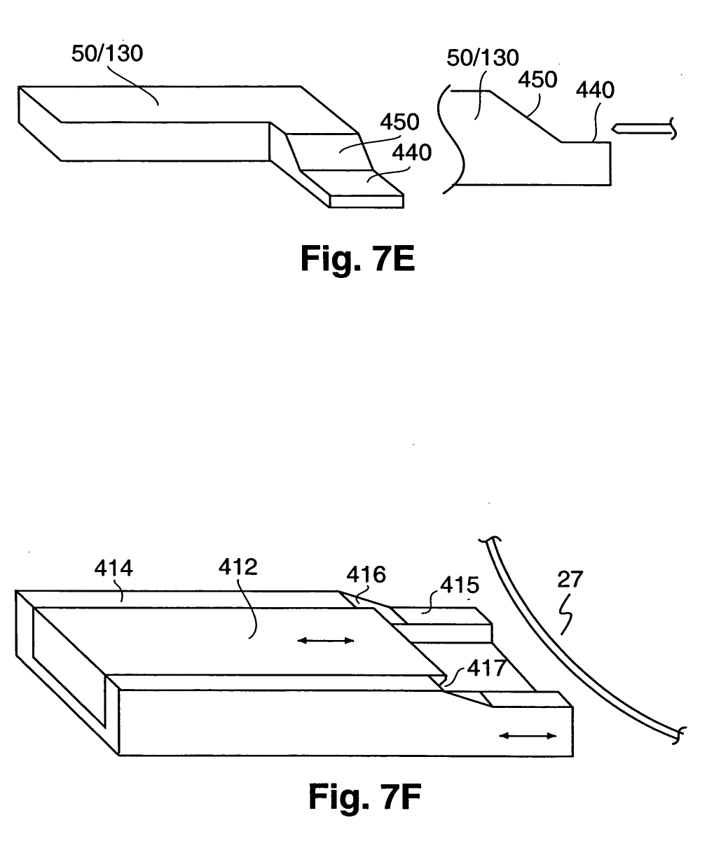

One aspect of the invention involves design of the grippers 50, 130 for securing the wafer 30 by only its side. FIGS. 7A-7B illustrate one configuration of the ends 150, 160. Here, the ends 150, 160 are notched to conform roughly to the profile 400 of the side of the wafer 30, so as to securely grip the wafer 30 when engaged while avoiding contact with any part of the wafer 30 above or below its edge. The invention is not limited to the specific shape shown, but rather contemplates any configuration of the ends 150, 160 that facilitates secure gripping of the edge profile 400 of the wafer 30.

The grippers 50, 130 in this configuration also have angled or beveled tips 410. By beveling the tip 410 proximate to the wafer 30 when the wafer 30 is engaged, the angled edges reflect light (or other electromagnetic radiation) at an angle away from the inspection units 20, and allow unobstructed illumination of both the top and bottom surfaces near the edge of the wafer 30. This reflection minimizes inspection problems due to glare from the grippers 50, 130. The invention is not limited to the exact configuration of the angled ends 410, but rather contemplates any configuration of the tips 410 that deflects or reflects incident radiation away from the inspection units 20. For example, the tips 410 can be beveled at different angles than that shown, or have arcuate curves designed in known fashion to reflect radiation in a preferential direction or directions, all while remaining within the scope of the invention.

FIGS. 7C-7D illustrate another configuration of the tips 410. Here, the gripper 50/130 is configured with a thinned portion 430 that has a thickness approximately equal to the thickness of the wafer 30, as shown. This thinned portion 430 further reduces the risk of obstructing the field of view of the inspection units 20. Because the thinned portion 430 lies in approximately the same plane as the wafer 30, its surfaces also do not risk reflecting radiation up to the inspection units 20, much like the beveled ends 410 of FIGS. 7A-7B.

FIGS. 7E-7F illustrate further configurations of the tips 410. In FIG. 7E, the gripper 50/130 is configured with a ledge 440 that does not grip the wafer 30, but instead supports the wafer 30 upon it. Grippers 50/130 equipped in this fashion need not grip the wafer 30 in the sense of compressibly engaging it, and as a result generate fewer stresses upon the wafer 30 than some other configurations do. The grippers 50/130 can also include angled or beveled portions 450 as in the embodiments of FIGS. 7A-7B, so as to offer the added advantage of less interference from reflected radiation. In FIG. 7F, the gripper 50/130 is configured with both a ledge 440 and a slidable portion 450 with ends 150, 160 configured as in FIG. 7A. In operation, the wafer 30 is placed on the ledge 440 so as to be supported in the vertical direction, and the slidable portion 450 is slid forward to engage the edge 60 as before, so as to support the wafer 30 in the horizontal plane as well. This configuration may be preferable in embodiments where wafers 30 must be held as securely as possible. This configuration also produces fewer compressive stresses within the wafer 30 as compared to configurations employing grippers 50/130 as in FIG. 2, as the wafer 30 is partially supported by the ledge 440. Various embodiments of the invention can employ any combination of these tip 410 designs, while remaining within the scope of the invention.

The foregoing description, for purposes of explanation, used specific nomenclature to provide a thorough understanding of the invention. However, it will be apparent to one skilled in the art that the specific details are not required in order to practice the invention. Thus, the foregoing descriptions of specific embodiments of the present invention are presented for purposes of illustration and description. They are not intended to be exhaustive or to limit the invention to the precise forms disclosed. Many modifications and variations are possible in view of the above teachings. For example, wafers can be supported by movable arms that pivot in any direction, so long as they pivot so as to prevent interference with the inspection process. Also, the wafer can be gripped with grippers having any configuration that facilitates support of the wafer by only its side edges. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A substrate process chamber, comprising:
a chamber configured to receive a substrate;
a plurality of substrate supports, the substrate supports configured to engage the substrate so as to handle the substrate within the chamber; and
support arms configured to engage the substrate so as to maintain the substrate proximate to the substrate supports, and to disengage from the substrate once the substrate is engaged by the substrate supports.

2. The substrate process chamber of claim 1 wherein the support arms are further configured to re-engage the substrate, and wherein at least one of the plurality of substrate supports is movably configured to disengage the substrate when the substrate is engaged by the support arms.

3. The substrate process chamber of claim 1:
wherein the substrate has upper and lower surfaces located opposite each other, and a side edge located between the upper and lower surfaces; and
wherein the substrate supports are further configured to engage the side edge of the substrate so as to support the substrate along the side edge.

4. The substrate process chamber of claim 3 wherein the support arms are further configured to pivotably disengage from the substrate so as to expose the lower surface for inspection.

5. The substrate process chamber of claim 3 wherein the substrate supports have notched ends, the notched ends conforming generally to a profile of the side edge of the substrate.

6. The substrate process chamber of claim 5 wherein the substrate supports have beveled surfaces terminating approximately at the notched ends, the beveled surfaces configured to reflect radiation so as to facilitate the performance of a process upon the substrate.

7. The substrate process chamber of claim 5 wherein the substrate supports have thinned portions terminating approximately at the notched ends, the thinned portions having a thickness approximately equal to the thickness of the substrate, so as to facilitate simultaneous exposure of the upper and lower surfaces of the substrate.

8. The substrate process chamber of claim 1 wherein the substrate supports have at least one flattened portion configured to support the substrate thereupon.

9. The substrate process chamber of claim 1 wherein the chamber has a door, and wherein at least one of the substrate supports is coupled to the door.

10. An apparatus for facilitating the support of a substrate within a chamber, comprising:
a bracket; and
movable arms pivotally affixed to the bracket, the arms configured to move between a first position engaging a substrate so as to facilitate movement of the substrate, and a second position disengaged from the substrate so as to facilitate the performance of a process upon the substrate.

11. The apparatus of claim 10 wherein in the first position, the substrate is supported upon the arms, and wherein in the second position, the arms are pivoted away from a surface of the substrate so as to facilitate the performance of a process upon the substrate.

12. The apparatus of claim 10 further comprising a gripping member coupled to the bracket, the gripping member having an end configured to engage a side of the substrate so as to facilitate a gripping of the substrate while the arms are moved to the second position.

13. The apparatus of claim 12 wherein the gripping member is slidably coupled to the bracket so as to slide between a first support position away from the substrate, and a second support position, the second support position placing the end proximate to the side of the substrate.

14. The apparatus of claim 12 wherein the substrate has an upper surface and an opposite lower surface, the side located between the upper and lower surfaces, and wherein the end of the gripping member is configured to engage the side of the substrate so as to support the substrate along the side.

15. The apparatus of claim 14 wherein the end is a notched end conforming generally to a profile of the edge of the substrate.

16. The apparatus of claim 12 wherein the gripping member has a beveled surface terminating approximately at the end, the beveled surface angled relative to the upper and lower surfaces so as to facilitate inspection of the substrate by reflecting radiation away from the substrate.

17. The apparatus of claim 12 wherein the gripping member has a thinned portion terminating approximately at the end, the thinned portion having a thickness approximately equal to the thickness of the substrate, so as to facilitate simultaneous exposure of the upper and lower surfaces of the substrate.

18. The apparatus of claim 12 wherein the gripping member has a flattened portion configured to support the substrate thereupon.

19. A method of positioning a substrate, comprising:
receiving a substrate upon an arm;
engaging the substrate with the support members; and
retracting the arm from the substrate so as to expose the substrate for the performance of a process thereon.

20. The method of claim 19 further comprising pivotably moving the arm proximate to the substrate so as to support the substrate with the arm, and disengaging the support members from the substrate.

21. The method of claim 19 wherein the substrate has a side edge located between an upper surface and an oppositely located lower surface, and wherein the engaging further comprises engaging the side edge of the substrate with the support member so as to support the substrate along the side edge.

22. The method of claim 21 wherein the engaging further comprises placing a notched end of the support member against the side edge of the substrate, the notched end conforming generally to a profile of the side edge, so as to facilitate support of the side edge by the notched end.

23. The method of claim 21 wherein the retracting further comprises exposing the upper surface and the lower surface of the substrate so as to facilitate the simultaneous inspection of both the upper surface and the lower surface.

24. The method of claim 19 further comprising reflecting radiation away from the substrate so as to facilitate inspection of the substrate.
